(19) United States
(12) Patent Application Publication
(10) Pub. No.: US 2025/0301831 A1
(43) Pub. Date: Sep. 25, 2025

(54) HIGH-VOLTAGE LIGHT-EMITTING DIODE CHIP

(71) Applicant: HUAIAN AUCKSUN OPTOELECTRONICS TECHNOLOGY CO., LTD, Huaian, Jiangsu (CN)

(72) Inventors: Yang Zhao, Huaian, Jiangsu (CN); Linqing Song, Huaian, Jiangsu (CN); HanChung Liao, Huaian, Jiangsu (CN); Ling Lu, Huaian, Jiangsu (CN)

(21) Appl. No.: 18/862,179

(22) PCT Filed: Dec. 29, 2023
(86) PCT No.: PCT/CN2023/143412

§ 371 Date: Nov. 1, 2024

(30) Foreign Application Priority Data
Dec. 29, 2022 (CN) 202211715903.9

(51) Int. Cl. H10H 20/831; H10H 20/812

(52) U.S. Cl. CPC H10H 20/831; H10H 20/812

(57) ABSTRACT

Provided in is a high-voltage light-emitting diode chip, including: a substrate; at least two light-emitting units, which are arranged on a surface of the substrate, wherein each light-emitting unit includes an N-type semiconductor layer, a multi-quantum well layer and a P-type semiconductor layer; an N-electrode layer, which is electrically connected to the N-type semiconductor layer of one of the light-emitting units; a P-electrode layer, which is electrically connected to the P-type semiconductor layer of the other one of the light-emitting units; and connection electrodes, each of which includes a P-side connection portion electrically connected to the P-type semiconductor layer, an N-side connection portion electrically connected to the N-type semiconductor layer, and an intermediate connection portion connecting the P-side connection portion to the N-side connection portion, at least one connection electrode being of a continuous bent structure.

### CROSS-REFERENCE TO RELATED APPLICATION

The present disclosure claims the priority to the Chinese patent application with the filling No. 202211715903.9 filed with the Chinese Patent Office on Dec. 29, 2022, and entitled “HIGH-VOLTAGE LIGHT-EMITTING DIODE CHIP”, the contents of which are incorporated herein by reference in entirety.

### TECHNICAL FIELD

The present disclosure relates to the technology field of semiconductors, and particularly to a high-voltage light-emitting diode chip.

### BACKGROUND ART

A light-emitting diode (LED for short) is a commonly used light-emitting device, which has the advantages of low voltage, low power consumption, small size, long life, and high safety factor. It is widely used in fields such as lighting and display. A high-voltage light-emitting diode (HV-LED) is made by dividing a large-sized chip into multiple small light-emitting units during the chip preparation process, and then connecting each light-emitting unit in series through electrodes, thereby achieving a LED with low current, high voltage and high power. The HV-LED chip reduces the driving cost and decreases the wire bonding operation at the packaging plant, thereby making it an LED product with market prospects.

In the currently common HV-LED chips, a single chip is provided with a connecting electrode with multiple branches. The current diversion caused by multiple electrodes leads to uneven current distribution on the surface of the HV-LED chip, thereby reducing the luminous efficiency.

### SUMMARY

In view of this, the objective of the present disclosure is to provide a high-voltage light-emitting diode chip to solve the problem of uneven current distribution on the surface of HV-LED chips in the prior art due to the current diversion by multiple branches of the electrode, thereby reducing current loss and improving the luminous efficiency of HV-LED chips.

The present disclosure provides a high-voltage light-emitting diode chip, including: a substrate and at least two light-emitting units arranged on a surface of the substrate, wherein each light-emitting unit includes an N-type semiconductor layer, a multiple quantum well layer, and a P-type semiconductor layer;
an N electrode layer electrically connected to the N-type semiconductor layer of one of the light-emitting units;
a P electrode layer electrically connected to the P-type semiconductor layer of another light-emitting unit; and
a connecting electrode including a P-side connecting part electrically connected to the P-type semiconductor layer, an N-side connecting part electrically connected to the N-type semiconductor layer, and an intermediate connecting part connecting the P-side connecting part and the N-side connecting part,
wherein at least one connecting electrode is of a continuous curved structure.

In one optional embodiment of the present disclosure, the curved structure includes at least two curved parts.

In one optional embodiment of the present disclosure, when at least two light-emitting units are arranged in a first direction, two adjacent light-emitting units are electrically connected by a first connecting electrode in a continuous curved structure. The first connecting electrode includes a first N-side connecting part located on the N-type semiconductor layer, a first P-side connecting part located on the P-type semiconductor layer, and a first intermediate connecting part that respectively connects the first N-side connecting part and the first P-side connecting part,
wherein the first P-side connecting part includes at least two curved parts, and the first N-side connecting part includes at least one curved part.

In one optional embodiment of the present disclosure, when a number of the first connecting electrodes is greater than or equal to 2, the structures of the first connecting electrodes are the same.

In one optional embodiment of the present disclosure, the N electrode layer includes an N-side main electrode and an N-side branch electrode, and the P electrode layer includes a P-side main electrode, a first P-side branch electrode, and a second P-side branch electrode.

A first part of the first connecting electrode extends around the N-side branch electrode of the N electrode layer, and a second part of the first connecting electrode extends into a spatial structure formed by the first P-side branch electrode and the second P-side branch electrode of the P electrode layer.

In one optional embodiment of the present disclosure, when at least two light-emitting units are arranged in the first direction and at least two light-emitting units are arranged in a second direction, the first connecting electrode connects two adjacent light-emitting units in the first direction, and the second connecting electrode connects two adjacent light-emitting units in the second direction. The structures of the first connecting electrode and the second connecting electrode are different, wherein the first direction and the second direction are different.

In one optional embodiment of the present disclosure, the second connecting electrode is of a discontinuous curved structure or a continuous curved structure. When the second connecting electrode is of a continuous curved structure, the number of curved parts of the second connecting electrode is different from the number of curved parts of the first connecting electrode.

In one optional embodiment of the present disclosure, a first part of one of the first connecting electrodes extends around the N-side branch electrode of the N electrode layer, and a second part of one of the first connecting electrodes extends into a first part of the second connecting electrode configured to connect two adjacent light-emitting units arranged in the second direction. A first part of another one of the first connecting electrodes extends around the second part of the second connecting electrode, and a second part of another one of the first connecting electrodes extends into the spatial structure formed by the first P-side branch electrode and the second P-side branch electrode of the P electrode layer.

In one optional embodiment of the present disclosure, the first P-side connecting part forms a first annular structure with an opening on the P-type semiconductor layer, wherein the first annular structure is a circular ring, a rectangular ring, a square ring, or a polygonal ring.

In one optional embodiment of the present disclosure, an opening width of the first P-side connecting part is smaller than a short side of the light-emitting unit where the first P-side connecting part is located.

In one optional embodiment of the present disclosure, a width of the first intermediate connecting part is greater than a width of the first N-side connecting part or a width of the first P-side connecting part.

In one optional embodiment of the present disclosure, a bridging region is provided between adjacent light-emitting units, and the first intermediate connecting part is arranged at an edge position away from a center position of the bridging region.

In one optional embodiment of the present disclosure, the first part of the second connecting electrode includes two curved parts, wherein a ratio of an extension length of one of the curved parts in the second direction to an extension length of another one of the curved parts in the second direction is between 1 and 4.

In one optional embodiment of the present disclosure, when the first part of another one of the first connecting electrodes extends around the second part of the second connecting electrode, a sum of vertical distances between long sides of the light-emitting unit and the first part of the first connecting electrode, respectively, is not greater than a target distance value. The target distance value is the sum of the vertical distances between the first part of the first connecting electrode and the second parts of the second connecting electrode, respectively.

The beneficial effects of the present disclosure compared to the prior art are as follows.

In the high-voltage light-emitting diode chip provided in the present disclosure, a connecting electrode includes a P-side connecting part electrically connected to the P-type semiconductor layer, an N-side connecting part electrically connected to the N-type semiconductor layer, and an intermediate connecting part connecting the P-side connecting part and the N-side connecting part, wherein at least one connecting electrode is of a continuous curved (bent shape) structure. The present disclosure enables the N electrode layer and the P electrode layer to be connected end-to-end by providing the connecting electrode of a continuous curved structure, thereby enabling unidirectional conduction of current in the high-voltage light-emitting diode chip. This can solve the problem of uneven current distribution on the surface of high-voltage light-emitting diode chips in the prior art due to the current diversion by multiple electrodes, thereby reducing current loss and improving the luminous efficiency of high-voltage light-emitting diode chips.

In order to make the above objectives, features, and advantages of the present disclosure more obvious and easier to understand, the following better embodiments, together with the attached drawings, are described in detail as follows.

### BRIEF DESCRIPTION OF DRAWINGS

To more clearly illustrate the technical solutions of the embodiments of the present disclosure, the following will briefly introduce the drawings used in the embodiments. It should be understood that the following drawings only show some embodiments of the present disclosure, and therefore they should not be regarded as a limitation on the scope. Those ordinary skilled in the art can also obtain other related drawings based on these drawings without inventive effort.

FIG. 1 is a schematic diagram of a planar structure of a first high-voltage light-emitting diode chip provided in the embodiment of the present disclosure;

FIG. 2 is a sectional view along A1-A1 in FIG. 1;

FIG. 3 is a sectional view along B1-B1 in FIG. 1;

FIG. 4 is a sectional view along C1-C1 in FIG. 1;

FIG. 5 is a schematic diagram of a planar structure of a second high-voltage light-emitting diode chip provided in the embodiment of the present disclosure;

FIG. 6 is a schematic diagram of a planar structure of a third high-voltage light-emitting diode chip provided in the embodiment of the present disclosure;

FIG. 7 is a schematic diagram of a planar structure of a fourth high-voltage light-emitting diode chip provided in the embodiment of the present disclosure;

FIG. 8 is a sectional view along A2-A2 in FIG. 7;

FIG. 9 is a sectional view along B2-B2 in FIG. 7;

FIG. 10 is a sectional view along C2-C2 in FIG. 7;

FIG. 11 is a sectional view along D2-D2 in FIG. 7;

FIG. 12 is a schematic diagram of a partial structure of the fourth high-voltage light-emitting diode chip provided in the embodiment of the present disclosure; and

FIG. 13 is a schematic diagram of a planar structure of a fifth high-voltage light-emitting diode chip provided in the embodiment of the present disclosure.

### REFERENCE NUMERALS

100, 700—substrate;
101, 501, 601, 701, 801—N electrode layer; 1011, 7011—N-side main electrode; 1012, 7012—N-side branch electrode; 10121, 70121—first N-side extension part; 10122, 70122—second N-side extension part;
102, 502, 602, 702, 802—P electrode layer; 1021, 7021—P-side main electrode; 1022, 7022—first P-side branch electrode; 1023, 7023—second P-side branch electrode; 10231, 70231—second P-side extension part; 10232, 70232—third P-side extension part;
200, 210—N-type semiconductor layer;
900, 910—P-type semiconductor layer;
300, 310—multiple quantum well layer;
400, 410—insulating protective layer;
500, 510—current spreading layer;
610—current blocking layer;
110, 640, 710—first light-emitting unit; 120, 620, 720—second light-emitting unit; 130, 730—third light-emitting unit; 740—fourth light-emitting unit; 750—fifth light-emitting unit; 760—sixth light-emitting unit;
140, 150, 630, 770, 780, 790, 890—first connecting electrode;
1401—first N-side connecting part; 1402—first intermediate connecting part; 1403—first P-side connecting part;
14011, 14012, 14013, 14014, 16011, 16012, 16013, 16014, 18011, 18012, 18013, 18014, 18015, 28011, 28012—curved part;
810, 820, 880—second connecting electrode;
8201—second N-side connecting part;
8202—second P-side connecting part;
8203—second intermediate connecting part.

### DETAILED DESCRIPTION OF EMBODIMENTS

In order to make the objective, technical solutions, and advantages of the embodiments of the present disclosure clearer, the following description will provide a clear and comprehensive explanation of the technical solutions in the embodiments of the present disclosure with reference to the drawings in the embodiments of the present disclosure. Clearly, the described embodiments are part of the embodiments of the present disclosure and not the entire embodiments. The components of embodiments of the present disclosure which are generally described and illustrated in the drawings herein can be arranged and designed in a variety of different configurations. Accordingly, the following detailed description of the embodiments of the present disclosure provided in the drawings is not intended to limit the scope of the present disclosure for which protection is claimed, but merely represents selected embodiments of the present disclosure. Based on the embodiments in the present disclosure, all other embodiments obtained of those of skill in the art of without making inventive efforts are within the scope of protection of the present disclosure.

In the description of the embodiments of the present disclosure, it should be noted that the orientation or positional relationship indicated by the terms “up”, “down”, “left”, “right”, “vertical”, “horizontal”, “inside”, “outside”, etc. is based on the orientation or positional relationship shown in the drawings or the orientation or positional relationship in which the product of the present disclosure is customarily placed when used. It is intended only to facilitate the description of the present disclosure and to simplify the description, and not to indicate or imply that the devices or elements referred to must have a particular orientation, be constructed and operated in a particular orientation. Accordingly, it is not to be construed as a limitation of the present disclosure. In addition, the terms “first”, “second”, and “third” are only used to distinguish the descriptive and are not to be construed as indicating or implying relative importance.

In addition, the terms such as “horizontal” and “vertical” do not mean that elements are required to be absolutely horizontal or overhanging, but can be slightly inclined. For example, “horizontal” only means that its direction is more horizontal than “vertical”, and it does not mean that the structure must be completely horizontal, but can be slightly inclined.

In the description of the embodiments of the present disclosure, it is further important to note that unless otherwise clearly stipulated and limited, the terms “provide”, “mount”, “interconnect”, and “connect” should be understood in a broad sense, for example, it can be a fixed connection, a detachable connection, or an integral connection; it can be a mechanical connection, or an electrical connection; and it can be a direct connection, an indirect connection through an intermediary, or an internal communication between two components. Those of ordinary skill in the art can understand the meanings of the above terms in the present disclosure according to specific situations.

First, the application scenarios to which the present disclosure can be applied are introduced as follows.

In the currently common HV-LED chips, a single chip is provided with a connecting electrode with multiple branches. The current diversion caused by multiple electrodes leads to uneven current distribution on the surface of the HV-LED chip, thereby reducing the luminous efficiency. In addition, the electrode arrangement of HV-LED chips is generally set such that the number of branches of the P electrode is greater than that of the N electrode. Meanwhile, most N electrodes adopt a linear N electrode, and the bridging regions of single chips are mostly arranged at the center position of the single chip to ensure more uniform current diffusion at the injection point. However, this structure greatly limits the arrangement of the branches of the P electrode in HV-LED chip, resulting in multiple branches of the P electrode provided between other multiple branches of the P electrode. This causes the distance between the injection points of the P electrode and N electrode to be too close, which not only affects the electrode arrangement but also is unfavorable for current conduction.

In view of this, the embodiments of the present disclosure provide a high-voltage light-emitting diode chip to solve the technical problems mentioned above, thereby reducing current loss and further improving the luminous efficiency of HV-LED chips.

The embodiments of the present disclosure provide a high-voltage light-emitting diode chip, including: a substrate and at least two light-emitting units arranged on a surface of the substrate, wherein each light-emitting unit includes an N-type semiconductor layer, a multiple quantum well layer, and a P-type semiconductor layer; an N electrode layer electrically connected to the N-type semiconductor layer of one of the light-emitting units; a P electrode layer electrically connected to the N electrode layer with the P-type semiconductor layer of another light-emitting unit; and a connecting electrode including a P-side connecting part electrically connected to the P-type semiconductor layer, an N-side connecting part electrically connected to the N-type semiconductor layer, and an intermediate connecting part connecting the P-side connecting part and the N-side connecting part, wherein at least one connecting electrode is of a continuous curved structure.

In one optional embodiment, the substrate can be a transparent non-conductive substrate, or a conductive substrate. For example, the substrate material can be sapphire. Illustrated here is an example with the substrate being a sapphire substrate, but it is not limited thereto.

In one optional embodiment, the high-voltage light-emitting diode chip includes multiple light-emitting units, and a bridging region is arranged between every two adjacent light-emitting units. Each light-emitting unit includes an N-type semiconductor layer, a multiple quantum well layer, and a P-type semiconductor layer, and adjacent light-emitting units are electrically connected by connecting electrodes, wherein the connecting electrode includes a P-side connecting part electrically connected to the P-type semiconductor layer, an N-side connecting part electrically connected to the N-type semiconductor layer, and an intermediate connecting part connecting the P-side connecting part and the N-side connecting part, and at least one connecting electrode is of a continuous curved structure. Preferably, the curved structure includes at least two curved parts. Exemplarily, the curved structure is similar to an “S” shape, a shape of a Chinese character “ [symbol] ”, or a shape of a Chinese character “ [symbol] ”, where the “S” shaped connecting electrode includes four curved parts, and the “ [symbol] ” shaped connecting electrode includes six curved parts. Specifically, the bending manner of the first part and the second part of the connecting electrode is related to the arrangement manner and size of the light-emitting units, and the shape of the N electrode layer and the P electrode layer.

In one optional embodiment, when at least two light-emitting units are arranged in a first direction, two adjacent light-emitting units are electrically connected by a first connecting electrode in a continuous curved structure. The first connecting electrode includes a first N-side connecting part located on the N-type semiconductor layer, a first P-side connecting part located on the P-type semiconductor layer, and a first intermediate connecting part that respectively connects the first N-side connecting part and the first P-side connecting part, wherein the first P-side connecting part includes at least two curved parts, and the first N-side connecting part includes at least one curved part. Optionally, when a number of the first connecting electrodes is greater than or equal to 2, the structures of the first connecting electrodes are the same. Optionally, the N electrode layer includes an N-side main electrode and an N-side branch electrode, and the P electrode layer includes a P-side main electrode, a first P-side branch electrode, and a second P-side branch electrode. A first part of the first connecting electrode extends around the N-side branch electrode of the N electrode layer, and a second part of the first connecting electrode extends into a spatial structure formed by the first P-side branch electrode and the second P-side branch electrode of the P electrode layer. Optionally, a first part of one of the first connecting electrodes extends around the N-side branch electrode of the N electrode layer, and a second part of one of the first connecting electrodes extends into a first part of the second connecting electrode configured to connect two adjacent light-emitting units arranged in the second direction. A first part of another one of the first connecting electrodes extends around the second part of the second connecting electrode, and a second part of another one of the first connecting electrodes extends into the spatial structure formed by the first P-side branch electrode and the second P-side branch electrode of the P electrode layer.

In one optional embodiment, when at least two light-emitting units are arranged in the first direction and at least two light-emitting units are arranged in a second direction, the first connecting electrode connects two adjacent light-emitting units in the first direction, and the second connecting electrode connects two adjacent light-emitting units in the second direction. The structures of the first connecting electrode and the second connecting electrode are different, wherein the first direction and the second direction are different. The second connecting electrode is of a discontinuous curved structure or a continuous curved structure. When the second connecting electrode is of a continuous curved structure, the number of curved parts of the second connecting electrode is different from the number of curved parts of the first connecting electrode. Exemplarily, when two light-emitting units are arranged in the first direction and two light-emitting units are arranged in the second direction, two first connecting electrodes and one second connecting electrode are required to electrically connect the four light-emitting units. When two light-emitting units are arranged in the first direction and three light-emitting units are arranged in the second direction, three first connecting electrodes and two second connecting electrodes are required to electrically connect the six light-emitting units. The first direction is different from the second direction. Preferably, the first direction is perpendicular to the second direction. In the embodiment of the present disclosure, the first direction is vertical, i.e., the “Y direction”, and the second direction is horizontal, i.e., the “X direction”. In this way, the structure of any light-emitting unit is the square structure, thus facilitating chip splicing.

For example, when the high-voltage light-emitting diode chip is an 18V product, two light-emitting units are arranged in the first direction, and three light-emitting units are arranged in the second direction. The long side of each light-emitting unit is no greater than ½ of the long side of the substrate, and the short side of each light-emitting unit is no less than ⅓ of the short side of the substrate and no greater than ⅔ of the short side of the substrate. When the high-voltage light-emitting diode chip is a 6V product, 9V product, etc., the long side and the short side of each light-emitting unit can be flexibly adjusted so that the light-emitting units arranged on the substrate are reasonably distributed. This facilitates the extension of the N-side branch electrode of the N electrode layer and the first P-side branch electrode and the second P-side branch electrode of the P electrode layer, thereby lengthening the current transmission path and promoting current spreading.

In one optional embodiment, the first P-side connecting part forms a first annular structure with an opening on the P-type semiconductor layer, wherein the first annular structure is a circular ring, a rectangular ring, a square ring, or a polygonal ring.

In one optional embodiment, an opening width of the first P-side connecting part is smaller than a short side of the light-emitting unit where the first P-side connecting part is located. This can ensure that when arranging the first connecting electrode, the first connecting electrode is avoided to extend beyond the boundary of the light-emitting unit.

In one optional embodiment, a width of the intermediate connecting part is greater than a width of the N-side connecting part or a width of the P-side connecting part. The intermediate connecting part here can serve as the current injection point. Thus, widening the intermediate connecting part can prevent current accumulation at the bridging of the light-emitting unit. Preferably, a bridging region is provided between adjacent light-emitting units, and the first intermediate connecting part is arranged at an edge position away from a center position of the bridging region. The first intermediate connecting part here is arranged at the edge position away from the center position of the bridging region, which can avoid the current injection points of the N electrode layer and the P electrode layer being too close. This not only does not affect the electrode arrangement but also facilitates lateral current conduction.

In one optional embodiment, the N electrode layer includes an N-side main electrode and an N-side branch electrode, wherein the N-side branch electrode is of a curved structure. The P electrode layer includes a P-side main electrode and at least one P-side branch electrode, wherein the P-side branch electrode is of a curved structure. In the embodiment of the present disclosure, the electrode extension length of the N-side branch electrode is less than the short side of the substrate or the long side of the substrate of the light-emitting unit where the N-side branch electrode is located. The electrode extension length of at least one P-side branch electrode is less than the short side of the substrate or the long side of the substrate of the light-emitting unit where the P-side branch electrode is located. Preferably, the electrode extension length of the N-side branch electrode and the electrode extension length of at least one P-side branch electrode are both greater than half of the short side of the substrate and less than the short side of the substrate. This ensures the lengthening of the current transmission path, which is beneficial for current spreading.

Based on the N electrode layer and the P electrode layer described in the above embodiments, the first connecting electrode in the embodiment of the present disclosure includes a first N-side connecting part located on the N-type semiconductor layer, a first P-side connecting part located on the P-type semiconductor layer, and a first intermediate connecting part that respectively connects the first N-side connecting part and the first P-side connecting part. Exemplarily, the first N-side connecting part includes a first connecting extension part extending along the third direction or the first direction and a second connecting extension part extending along the second direction. The first P-side connecting part includes at least a third connecting extension part extending along the first direction and a fourth connecting extension part extending along the second direction. Exemplarily, the first N-side connecting part includes a first connecting extension part extending along the third direction, and the first connecting extension part is of an arc-shaped structure. Exemplarily, the first P-side connecting part includes a third connecting extension part extending along the first direction and two fourth connecting extension parts extending along the second direction. Optionally, the first P-side connecting part forms a first annular structure with an opening on the P-type semiconductor layer. Thus, the first connecting electrode can enable the N electrode layer and the P electrode layer to be connected end-to-end, thereby allowing unidirectional current conduction in the high-voltage light-emitting diode chip. This can solve the problem of uneven current distribution, thereby reducing current loss and improving the luminous efficiency of the high-voltage light-emitting diode chip.

Based on the N electrode layer and the P electrode layer described in the above embodiments, the second connecting electrode includes a second N-side connecting part located on the N-type semiconductor layer, a second P-side connecting part located on the P-type semiconductor layer, and a second intermediate connecting part that respectively connects the second N-side connecting part and the second P-side connecting part. The second P-side connecting part of the second connecting electrode includes at least one fifth connecting extension part extending along the first direction and a sixth connecting extension part extending along the second direction.

In an optional embodiment, the second intermediate connecting part is arranged at the center position of the bridging region between adjacent light-emitting units. This can ensure that the second connecting electrode accurately connects the adjacent first connecting electrodes, thus facilitating the electrode arrangement.

In one optional embodiment, the first part of the second connecting electrode includes two curved parts, wherein a ratio of an extension length of one of the curved parts in the second direction to an extension length of another one of the curved parts in the second direction is between 1 and 4.

In one optional embodiment, when the first part of another one of the first connecting electrodes extends around the second part of the second connecting electrode, a sum of vertical distances between long sides of the light-emitting unit and the first part of the first connecting electrode, respectively, is not greater than a target distance value. The target distance value is the sum of the vertical distances between the first part of the first connecting electrode and the second parts of the second connecting electrode, respectively. Exemplarily, the first P-side connecting part of the first connecting electrode includes a third connecting extension part extending along the first direction and two fourth connecting extension parts extending along the second direction. When the second N-side connecting part extends into the first annular structure formed by the first P-side connecting part, the sum of the vertical distances between the two fourth connecting extension parts of the first P-side connecting part and the second N-side connecting part is not less than the target distance value. The target distance value is the difference between the short side of the light-emitting unit where the first P-side connecting part is located and the opening width of the first P-side connecting part, and the opening width is the vertical distance between the two fourth connecting extension parts. This arrangement can prevent the current from being too concentrated in the region around the electrodes, which could result in excessively low current density at the chip boundaries and uneven light emission of the light-emitting units.

In an optional embodiment, the contour shape of the first N-side connecting part matches the contour shape of the second annular structure configured to accommodate the first N-side connecting part, and/or the contour shape of the first N-side connecting part matches the contour shape of the spatial structure configured to accommodate the first N-side connecting part.

Below are specific embodiments to illustratively describe the high-voltage light-emitting diode chip provided by the present disclosure, but it should be noted that the present disclosure is not limited to the embodiments described below.

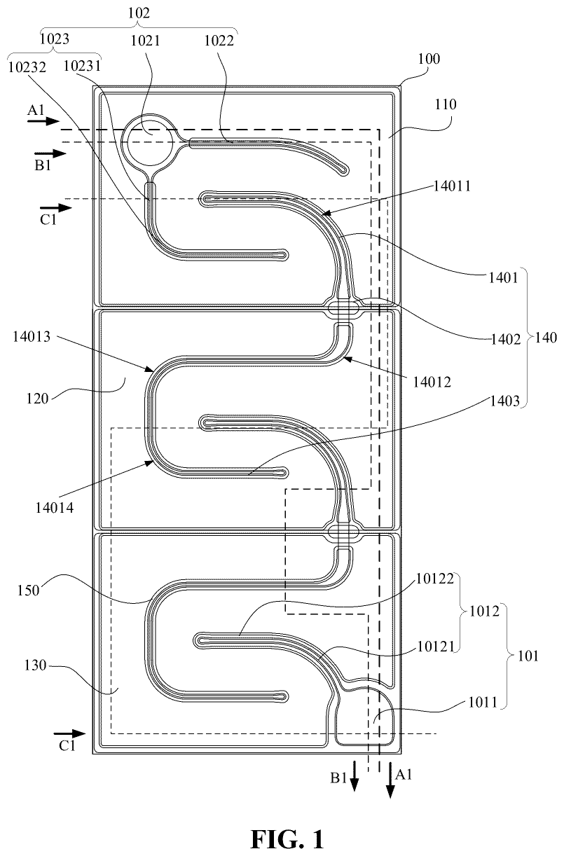

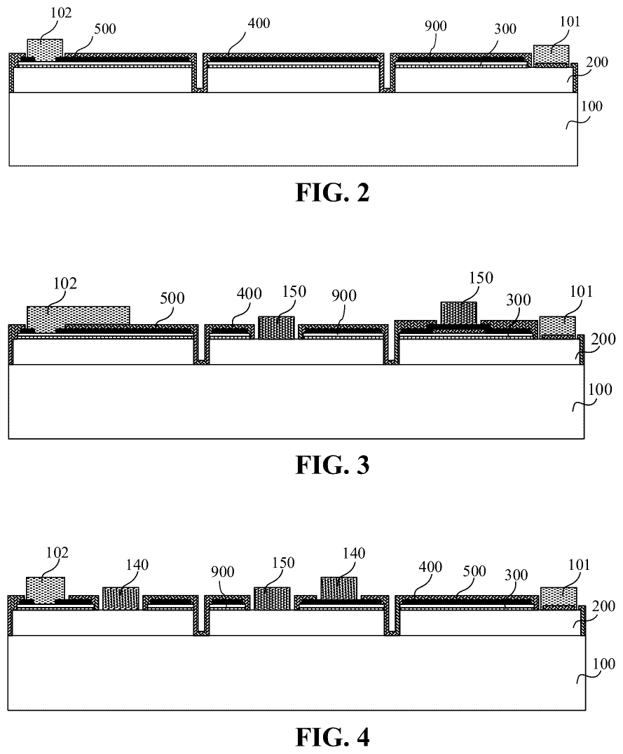

Referring to FIGS. 1 to 4, FIG. 1 is a schematic diagram of a planar structure of a first high-voltage light-emitting diode chip provided in the embodiment of the present disclosure, FIG. 2 is a sectional view along A1-A1 in FIG. 1, FIG. 3 is a sectional view along B1-B1 in FIG. 1, and FIG. 4 is a sectional view along C1-C1 in FIG. 1. As shown in FIG. 1 to FIG. 4, the embodiments of the present disclosure provide a high-voltage light-emitting diode chip, including: a substrate 100 and three light-emitting units arranged on a surface of the substrate 100, wherein each light-emitting unit includes an N-type semiconductor layer 200, a multiple quantum well layer 300, and a P-type semiconductor layer 900. The long side of each light-emitting unit is no greater than the long side of the substrate, and the short side of each light-emitting unit is no less than ¼ of the short side of the substrate and no greater than ⅓ of the short side of the substrate.

As shown in FIG. 1, the third light-emitting unit 130 is provided with an N electrode layer 101, wherein the N electrode layer 101 is electrically connected to the N-type semiconductor layer on the third light-emitting unit 130. The first light-emitting unit 110 is provided with a P electrode layer 102, wherein the P electrode layer 102 is electrically connected to the P-type semiconductor layer on the first light-emitting unit 110. Specifically, the N electrode layer 101 includes the N-side main electrode 1011 and the N-side branch electrode 1012. The N-side branch electrode 1012 includes a first N-side extension part 10121 extending in the third direction and a second N-side extension part 10122 extending in the second direction. The third direction is located between the first direction and the second direction, wherein the first direction is perpendicular to the second direction, the first direction is a vertical direction, and the second direction is a horizontal direction. Preferably, the first N-side extension part 10121 is of an arc-shaped structure, and the second N-side extension part 10122 is of a linear structure. The P electrode layer 102 includes the P-side main electrode 1021, the first P-side branch electrode 1022, and the second P-side branch electrode 1023. The first P-side branch electrode 1022 includes a first P-side extension part extending in the second direction. The second P-side branch electrode 1023 includes a second P-side extension part 10231 extending in the first direction and a third P-side extension part 10232 extending in the second direction. Preferably, the first P-side extension part includes a linear structure extending in the second direction and an arc-shaped structure extending in the third direction. The second P-side extension part 10231 and the third P-side extension part 10232 are connected in an arc shape.

On the basis of the P electrode layer 102 and the N electrode layer 101, when the high-voltage light-emitting diode chip includes three light-emitting units, the three light-emitting units are arranged in the first direction. The P electrode layer 102 is electrically connected to the P-type semiconductor layer of the first light-emitting unit 110, and the N electrode layer 101 is electrically connected to the N-type semiconductor layer of the third light-emitting unit 130, wherein the first direction is perpendicular to the second direction.

One end of the first connecting electrode 150 surrounds the N-side branch electrode of the N electrode layer 101 of the third light-emitting unit 130. The other end of the first connecting electrode 150 extends to the first annular structure formed by the first connecting electrode 140 located on the second light-emitting unit 120. The other end of the first connecting electrode 140 extends to the spatial structure formed by the first P-side branch electrode and the second P-side branch electrode of the P electrode layer 102 of the first light-emitting unit 110. Optionally, the structures of the first connecting electrode 150 and the first connecting electrode 140 are the same. This facilitates etching the shape of each first connecting electrode (140, 150), which is in the region of vertical projection on the substrate. Both the first connecting electrode 150 and the first connecting electrode 140 include four curved parts. For example, the first connecting electrode 140 includes four curved parts (14011, 14012, 14013, 14014). In the first connecting electrode 140, here, the first connecting electrodes (140, 150) are arranged in an “inverted S-shape” to achieve the diffusion uniformity of current as much as possible.

As shown in FIG. 2 to FIG. 4, the insulating protective layer 400 covering the surface of a portion of the P-type semiconductor layer 900 can be a DBR reflective layer composed of SiO₂/TiO₂, thereby increasing the reflectivity of light. Additionally, the insulating protective layer 400 can also be a single-layer insulating layer composed of SiO₂.

The surface of a portion of the P-type semiconductor layer 900 is also provided with a current spreading layer 500, wherein the current spreading layer 500 is a transparent conductive layer, usually made of ITO, with a current spreading function.

Specifically, as shown in FIG. 1, the first connecting electrode 140 includes a first N-side connecting part 1401 located on the N-type semiconductor layer, a first P-side connecting part 1403 located on the P-type semiconductor layer, and a first intermediate connecting part 1402 that respectively connects the first N-side connecting part 1401 and the first P-side connecting part 1403. The first P-side connecting part 1403 includes three curved parts, and the first N-side connecting part 1401 includes one curved part. Preferably, the first P-side connecting part 1403 forms a first annular structure with an opening on the P-type semiconductor layer; the first annular structure here is a rectangular ring. Preferably, an opening width of the first P-side connecting part 1403 is smaller than a short side of the light-emitting unit where the first P-side connecting part 1402 is located. Preferably, a width of the first intermediate connecting part 1402 is greater than a width of the first N-side connecting part 1401 or a width of the first P-side connecting part 1403, which can prevent current accumulation. Moreover, a bridging region is provided between adjacent light-emitting units. The first intermediate connecting part 1402 is arranged at the edge position away from the center position of the bridging region, which can avoid the current injection points of the N electrode layer 101 and the P electrode layer 102 being too close. This not only does not affect the electrode arrangement but also facilitates lateral current conduction.

It should be noted that in the embodiment of the present disclosure, the arc structure in the first connection electrode, due to its relatively smooth contour, facilitates etching, on the high-voltage light-emitting diode chip, the shape of the vertical projection region of the first connection electrode on the substrate.

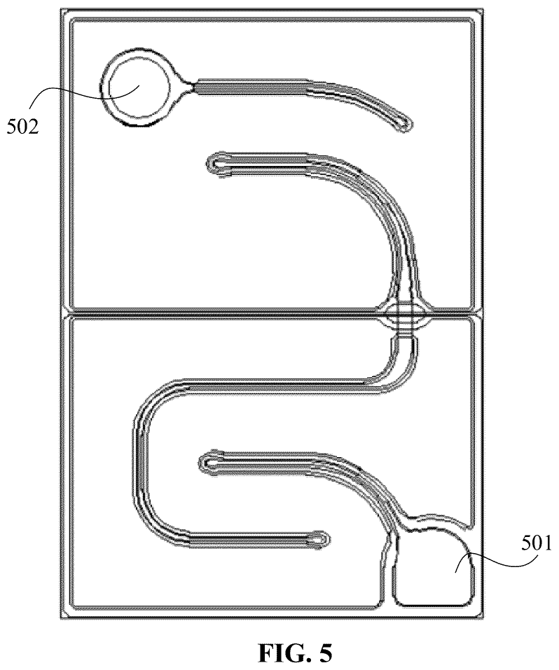

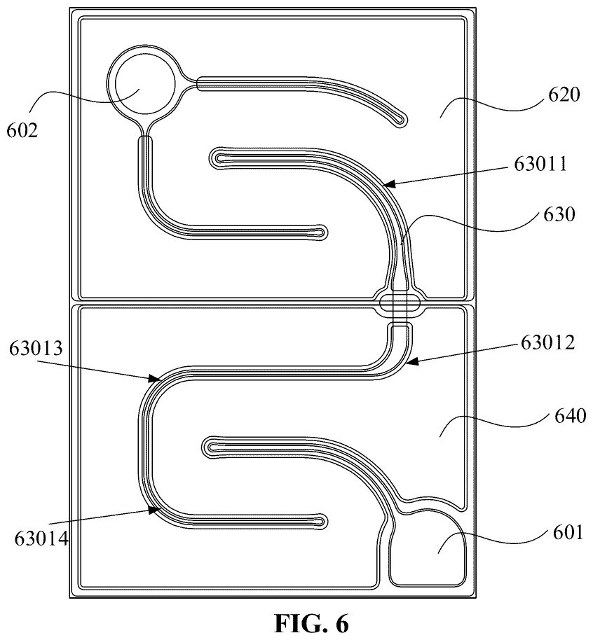

Additionally, the present disclosure also provides a second high-voltage light-emitting diode chip. As shown in FIGS. 5 and 6, when the high-voltage light-emitting diode chip includes two light-emitting units, the two light-emitting units are arranged in the first direction, with the P electrode layer 602 electrically connected to the P-type semiconductor layer of the second light-emitting unit 620 and the N electrode layer 601 electrically connected to the N-type semiconductor layer of the first light-emitting unit 640. Alternatively, as shown in FIG. 5, the P electrode layer 502 can be electrically connected to the P-type semiconductor layer of one of the light-emitting units, and the N electrode layer 501 can be electrically connected to the N-type semiconductor layer of another light-emitting unit. Furthermore, the first connecting electrode 630 includes four curved parts (63011, 63012, 63013, 63014). For specific details. Specifically, it is shown in FIGS. 5 and 6 and will not be repeated herein.

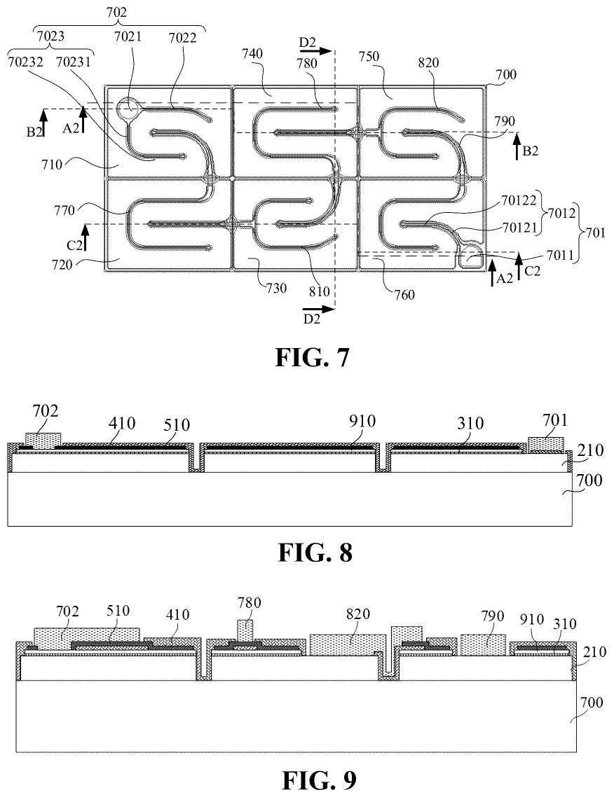

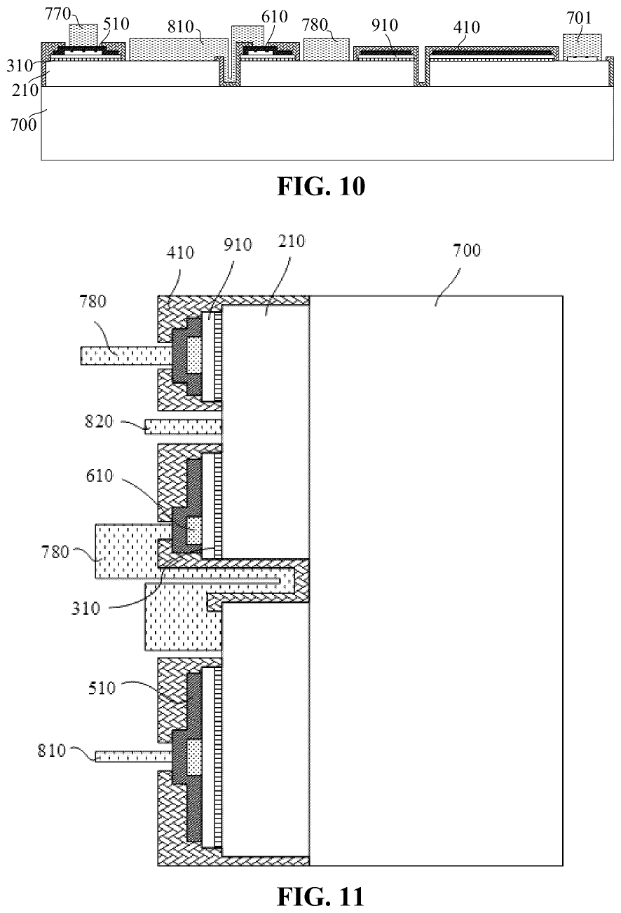

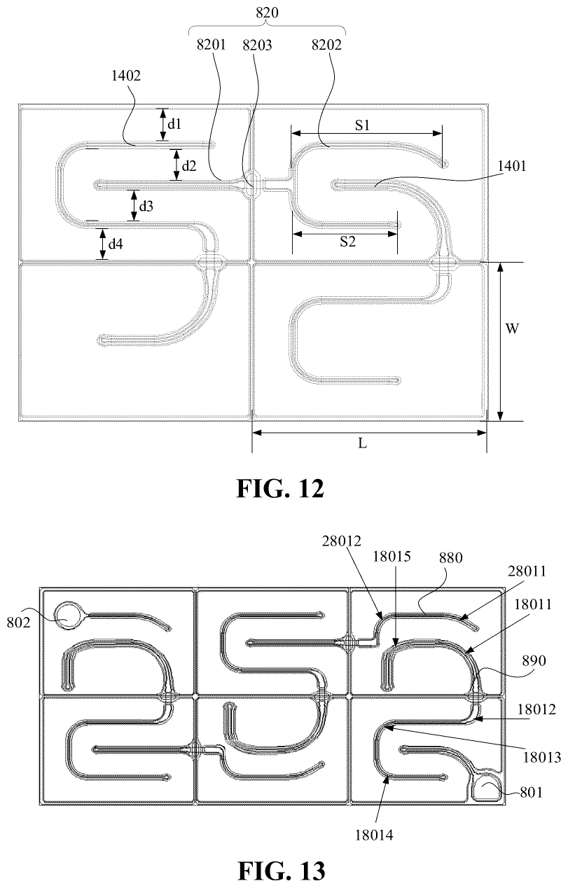

Referring to FIGS. 7 to 12, FIG. 7 is a schematic diagram of a planar structure of a fourth high-voltage light-emitting diode chip provided in the embodiment of the present disclosure, FIG. 8 is a sectional view along A2-A2 in FIG. 7, FIG. 9 is a sectional view along B2-B2 in FIG. 7, FIG. 10 is a sectional view along C2-C2 in FIG. 7, FIG. 11 is a sectional view along D2-D2 in FIG. 7, and FIG. 12 is a schematic diagram of a partial structure of the fourth high-voltage light-emitting diode chip provided in the embodiment of the present disclosure. As shown in FIG. 7 to FIG. 12, the embodiments of the present disclosure provide a fourth high-voltage light-emitting diode chip, including: a substrate 700 and six light-emitting units arranged on a surface of the substrate 700, wherein each light-emitting unit includes an N-type semiconductor layer 210, a multiple quantum well layer 310, and a P-type semiconductor layer 910. The long side of each light-emitting unit is no greater than ½ of the long side of the substrate, and the short side of each light-emitting unit is no less than ⅓ of the short side of the substrate and no greater than ⅔ of the short side of the substrate.

As shown in FIG. 7, the sixth light-emitting unit 760 is provided with an N electrode layer 701, wherein the N electrode layer 701 is electrically connected to the N-type semiconductor layer on the sixth light-emitting unit 760. The first light-emitting unit 710 is provided with a P electrode layer 702, wherein the P electrode layer 702 is electrically connected to the P-type semiconductor layer on the first light-emitting unit 710. Specifically, the N electrode layer 701 includes the N-side main electrode 7011 and the N-side branch electrode 7012. The N-side branch electrode 7012 includes a first N-side extension part 70121 extending in the third direction and a second N-side extension part 70122 extending in the second direction. The third direction is located between the first direction and the second direction, wherein the first direction is perpendicular to the second direction, the first direction is a vertical direction, and the second direction is a horizontal direction. Preferably, the first N-side extension part 70121 is of an arc-shaped structure, and the second N-side extension part 70122 is of a linear structure. The P electrode layer 702 includes the P-side main electrode 7021, the first P-side branch electrode 7022, and the second P-side branch electrode 7023. The first P-side branch electrode 7022 includes a first P-side extension extending in the second direction. The second P-side branch electrode 7023 includes a second P-side extension part 70231 extending in the first direction and a third P-side extension part 70232 extending in the second direction. Preferably, the first P-side extension part includes a linear structure extending in the second direction and an arc-shaped structure extending in the third direction. The second P-side extension part 70231 and the third P-side extension part 70232 are connected in an arc shape.

On the basis of the P electrode layer 702 and the N electrode layer 701, when the high-voltage light-emitting diode chip includes six light-emitting units, the six light-emitting units are arranged in the form of two along the first direction and three along the second direction. The light-emitting unit where the P electrode layer 702 is located is defined as the first light-emitting unit 710, and the light-emitting unit where the N electrode layer 701 is located is defined as the sixth light-emitting unit 760. The P electrode layer 702 can be electrically connected to the P-type semiconductor layer of the first light-emitting unit 710, and the N electrode layer 701 can be electrically connected to the N-type semiconductor layer of the six light-emitting unit 760.

One end of the first connecting electrode 790 surrounds the N-side branch electrode of the N electrode layer 701 of the sixth light-emitting unit 760 and extends to the second annular structure formed by the second connecting electrode 820 located on the fifth light-emitting unit 750. The other end of the second connecting electrode 820 extends to the first annular structure formed by the first connecting electrode 780 of the fourth light-emitting unit 740. The other end of the first connecting electrode 780 extends to the second annular structure formed by the second connecting electrode 810 of the third light-emitting unit 730. The other end of the second connecting electrode 810 extends to the first annular structure formed by the first connecting electrode 770 of the second light-emitting unit 720. The other end of the first connecting electrode 770 extends to the spatial structure formed by the first P-side branch electrode and the second P-side branch electrode of the P electrode layer 702 of the first light-emitting unit 710.

The structures of the first connecting electrode 770, the first connecting electrode 780, and the first connecting electrode 790 can be provided identically, and the structures of the second connecting electrode 810 and the second connecting electrode 820 can also be provided identically. This facilitates the etching of the shapes of the first connecting electrodes (770, 780, 790) and the second connecting electrodes (810, 820), which are in the region of vertical projection on the substrate. The first connecting electrodes (770, 780, 790) here are all arranged in an “inverted S-shape,” each including four curved parts. The first P-side connecting part includes three curved parts, and the first N-side connecting part includes one curved part to achieve the diffusion uniformity of current as much as possible.

As shown in FIG. 8 to FIG. 11, the insulating protective layer 410 covering the surface of a portion of the P-type semiconductor layer 910 can be a DBR reflective layer composed of SiO₂/TiO₂, thereby increasing the reflectivity of light. Additionally, the insulating protective layer 410 can also be a single-layer insulating layer composed of SiO₂.

The surface of a portion of the P-type semiconductor layer 910 is also provided with a current spreading layer 510, wherein the current spreading layer 510 is a transparent conductive layer, usually made of ITO, with a current spreading function.

The current blocking layer 610 is essentially an insulating layer, typically made of SiO₂. The current blocking layer 610 is typically located (1) below the first connecting electrode 770 and/or the second connecting electrode 810 to prevent the first connecting electrode 770 and/or the second connecting electrode 810 from directly contacting the substrate (sapphire substrate); (2) below the N electrode layer 701 and/or the P electrode 707. The current spreading layer 510 is arranged on the P-type semiconductor layer and further arranged between the current blocking layer 610 on the P-type semiconductor layer and the P electrode layer 102. The objective of the current blocking layer 610 here is to prevent current from flowing along the shortest path and to ensure that the current is distributed as evenly as possible over the N-type semiconductor layer and the P-type semiconductor layer through the current spreading layer 510.

The description of the first connecting electrode can refer to the above description regarding FIG. 5 and will not be repeated here.

Specifically, as shown in FIG. 12, the second connecting electrode 820 includes a second N-side connecting part 8201 located on the N-type semiconductor layer, a second P-side connecting part 8202 located on the P-type semiconductor layer, and a second intermediate connecting part 8203 that respectively connects the second N-side connecting part 8201 and the second P-side connecting part 8202. The second connecting electrode 820 is of a continuous curved structure, including three curved parts. Preferably, the second P-side connecting part 8202 forms a second annular structure with an opening on the P-type semiconductor layer; the second annular structure here is a rectangular ring. Additionally, the second intermediate connecting part 8203 is arranged at the center position of the bridging region between adjacent light-emitting units.

Optionally, as shown in FIG. 12, the second N-side connecting part 8201 of the second connecting electrode 820 is connected to the first P-side connecting part 1402 of the first connecting electrode, and the second N-side connecting part 8201 extends into the first annular structure formed by the first P-side connecting part 1402. The first N-side connecting part 1401 of the first connecting electrode 790 is connected to the second P-side connecting part 8202 of the second connecting electrode 820, and the first N-side connecting part 1401 extends into the second annular structure formed by the second P-side connecting part 8202.

Alternatively, as shown in FIG. 13, the N electrode layer 801 can be electrically connected to the N-type semiconductor layer of one of the light-emitting units, and the P electrode layer 802 can be electrically connected to the P-type semiconductor layer of another light-emitting unit. Exemplarily, the first N-side extension part of the first connecting electrode 890 is connected to the second P-side connecting part of the second connecting electrode 880. The first connecting electrode 890 includes five curved parts (18011, 18012, 18013, 18014, 18015), and the second connecting electrode 880 includes two curved parts (28011, 28012).

Additionally, the arc-shaped structure corresponding to the first connecting extension part in the first N-side connecting part has a radius equal to the radius of the arc-shaped structure in the first P-side extension part, thus making the contour shape of the first N-side connecting part match the contour shape of the spatial structure configured to accommodate the first N-side connecting part (not shown in FIG. 12, reference can be made to FIG. 7).

It should be noted that in the embodiment of the present disclosure, the arc structures in the first connection electrode and the second connection electrode, due to their relatively smooth contour, facilitate etching, on the high-voltage light-emitting diode chip, the shape of the vertical projection regions of the first connection electrode and the second connection electrode on the substrate.

Specifically, as shown in FIG. 12, preferably, the long side L of the light-emitting unit is not more than half the long side of the component, and the long side W of the light-emitting unit is not less than ⅓ of the short side of the component and not more than ⅔ of the short side of the component. The first part of the second connecting electrode 820 includes two curved parts, wherein a ratio of an extension length of one of the curved parts in the second direction to an extension length of another one of the curved parts in the second direction is between 1 and 4, i.e., S2/S1=1/4. Optionally, when the first part of another one of the first connecting electrodes extends around the second part of the second connecting electrode, a sum of vertical distances between long sides of the light-emitting unit and the first part of the first connecting electrode, respectively, is not greater than a target distance value. The target distance value is the sum of the vertical distances between the first part of the first connecting electrode and the second parts of the second connecting electrode, respectively, i.e., d1+d4≤d2+d3. This arrangement can prevent the current from being too concentrated in the region around the electrodes, which will result in low current density at the chip boundaries and uneven light emission of the light-emitting units.

It should be added that the above embodiments describe a high-voltage light-emitting diode chip with a regular mounting as an example. Additionally, the connecting electrodes in the embodiments of the present disclosure can also be applied to a high-voltage light-emitting diode chip with an inverted mounting. This will not be further elaborated here.

By the arrangement above, the embodiments of the present disclosure can enable the N electrode layer and the P electrode layer to be connected end-to-end, thereby enabling unidirectional conduction of current in the high-voltage light-emitting diode chip. This can solve the problem of uneven current distribution on the surface of high-voltage light-emitting diode chips in the prior art due to the current diversion by multiple electrodes, thereby reducing current loss and improving the luminous efficiency of high-voltage light-emitting diode chips. At the same time, widening the first intermediate connecting part of the first connecting electrode can prevent current accumulation at the bridging of the light-emitting units and can ensure more uniform current diffusion at the injection point. Moreover, the first intermediate connecting part is arranged at the edge position away from the center position of the bridging region, which can avoid the current injection points of the N electrode layer and the P electrode layer being too close. This not only does not affect the electrode arrangement but also facilitates lateral current conduction.

Finally, it should be noted that the above-described embodiments are only specific embodiments of the present disclosure to illustrate the technical solutions of the present disclosure, and not to limit them. The scope of protection of the present disclosure is not limited thereto. Although the present disclosure is described in detail with reference to the foregoing embodiments, it should be understood by those of ordinary skill in the art that, any person skilled in the art within the scope of the technology disclosed in the present disclosure is still possible to modify or readily conceivable changes to the technical solutions recorded in the foregoing embodiments, or to make equivalent substitutions to some of the technical features thereof; and these modifications, changes or substitutions, which do not make the essence of the corresponding technical solutions out of the spirit and scope of the technical solutions of the embodiments of the present disclosure, shall be covered within the scope of protection of the present disclosure. Therefore, the scope of protection of the present disclosure shall be stated to be subject to the scope of protection of the claims.

1. A high-voltage light-emitting diode chip, comprising: a substrate and at least two light-emitting units arranged on a surface of the substrate, wherein each light-emitting unit comprises an N-type semiconductor layer, a multiple quantum well layer, and a P-type semiconductor layer;
an N electrode layer, electrically connected to the N-type semiconductor layer of one of the light-emitting units;
a P electrode layer, electrically connected to the P-type semiconductor layer of another light-emitting unit; and
a connecting electrode, comprising a P-side connecting part electrically connected to the P-type semiconductor layer, an N-side connecting part electrically connected to the N-type semiconductor layer, and an intermediate connecting part connecting the P-side connecting part and the N-side connecting part, wherein
at least one connecting electrode is of a continuous curved structure.

2. The high-voltage light-emitting diode chip according to claim 1, wherein the curved structure comprises at least two curved parts.

3. The high-voltage light-emitting diode chip according to claim 1, wherein when at least two light-emitting units are arranged in a first direction, two adjacent light-emitting units are electrically connected by a first connecting electrode in the continuous curved structure; the first connecting electrode comprises a first N-side connecting part located on the N-type semiconductor layer, a first P-side connecting part located on the P-type semiconductor layer, and a first intermediate connecting part that respectively connects the first N-side connecting part and the first P-side connecting part, wherein
the first P-side connecting part comprises at least two curved parts, and the first N-side connecting part comprises at least one curved part.

4. The high-voltage light-emitting diode chip according to claim 3, wherein when the number of the first connecting electrodes is greater than or equal to 2, structures of the first connecting electrodes are the same.

5. The high-voltage light-emitting diode chip according to claim 3, wherein the N electrode layer comprises an N-side main electrode and an N-side branch electrode, and the P electrode layer comprises a P-side main electrode, a first P-side branch electrode, and a second P-side branch electrode; and
a first part of the first connecting electrode extends around the N-side branch electrode of the N electrode layer, and a second part of the first connecting electrode extends into a spatial structure formed by the first P-side branch electrode and the second P-side branch electrode of the P electrode layer.

6. The high-voltage light-emitting diode chip according to claim 3, wherein
when at least two light-emitting units are arranged in the first direction and at least two light-emitting units are arranged in a second direction, the first connecting electrode connects two adjacent light-emitting units in the first direction, and the second connecting electrode connects two adjacent light-emitting units in the second direction; and structures of the first connecting electrode and the second connecting electrode are different, wherein the first direction and the second direction are different.

7. The high-voltage light-emitting diode chip according to claim 6, wherein the second connecting electrode is of a discontinuous curved structure or a continuous curved structure, wherein when the second connecting electrode is of a continuous curved structure, the number of curved parts of the second connecting electrode is different from the number of the curved parts of the first connecting electrode.

8. The high-voltage light-emitting diode chip according to claim 6, wherein a first part of one of the first connecting electrodes extends around the N-side branch electrode of the N electrode layer, and a second part of the one of the first connecting electrodes extends into a first part of the second connecting electrode configured to connect two adjacent light-emitting units arranged in the second direction; and a first part of another one of the first connecting electrodes extends around a second part of the second connecting electrode, and a second part of the another one of the first connecting electrodes extends into the spatial structure formed by the first P-side branch electrode and the second P-side branch electrode of the P electrode layer.

9. The high-voltage light-emitting diode chip according to claim 3, wherein the first P-side connecting part forms a first annular structure with an opening on the P-type semiconductor layer, and the first annular structure is a circular ring, a rectangular ring, a square ring, or a polygonal ring.

10. The high-voltage light-emitting diode chip according to claim 9, wherein an opening width of the first P-side connecting part is smaller than a short side of a light-emitting unit where the first P-side connecting part is located.

11. The high-voltage light-emitting diode chip according to claim 1, wherein a width of the intermediate connecting part is greater than a width of the N-side connecting part or a width of the P-side connecting part.

12. The high-voltage light-emitting diode chip according to claim 3, wherein a bridging region is provided between adjacent light-emitting units, and the first intermediate connecting part is arranged at an edge position away from a center position of the bridging region.

13. The high-voltage light-emitting diode chip according to claim 8, wherein the first part of the second connecting electrode comprises two curved parts, and a ratio of an extension length of one of the curved parts in the second direction to an extension length of another one of the curved parts in the second direction is between 1 and 4.

14. The high-voltage light-emitting diode chip according to claim 8, wherein when the first part of the another one of the first connecting electrodes extends around the second part of the second connecting electrode, a sum of vertical distances between long sides of the light-emitting unit and the first part of the first connecting electrode, respectively, is not greater than a target distance value; and the target distance value is a sum of vertical distances between the first part of the first connecting electrode and second parts of the second connecting electrode, respectively.

15. The high-voltage light-emitting diode chip according to claim 5, wherein when at least two light-emitting units are arranged in the first direction and at least two light-emitting units are arranged in a second direction, the first connecting electrode connects two adjacent light-emitting units in the first direction, and the second connecting electrode connects two adjacent light-emitting units in the second direction; and structures of the first connecting electrode and the second connecting electrode are different, wherein the first direction and the second direction are different.

16. The high-voltage light-emitting diode chip according to claim 1, wherein the connecting electrode is similar to an “S” shape, a shape of a Chinese character “ [symbol] ”, or a shape of a Chinese character “ [symbol] ”.
